(19) United States
(12) Patent Application Publication
(10) Pub. No.: US 2008/0048283 A1
(43) Pub. Date: Feb. 28, 2008

(54) Image Sensor and Fabricating Method Thereof

(76) Inventor: JAE WON HAN, Soowon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/842,639

(22) Filed: Aug. 21, 2007

(30) Foreign Application Priority Data
Aug. 23, 2006 (KR) 10-2006-0080134

(51) Int. Cl. H01L 31/0232; H01L 31/18

(52) U.S. Cl. 257/432; 438/71; 257/E31.128

(57) ABSTRACT

An image sensor is provided. The image sensor can include an isolation layer, a transistor region, and a photodiode region on a semiconductor substrate. A plurality of holes can be formed in the substrate of the photodiode region. The plurality of holes can be densely formed in the substrate. At least one hole can be formed in a minimum design rule size.

### CROSS-REFERENCE TO RELATED APPLICATION

The present application claims the benefit under 35 U.S.C. § 119 of Korean Patent Application No. 10-2006-0080134, filed Aug. 23, 2006, which is hereby incorporated by reference in its entirety.

### BACKGROUND

An image sensor is a semiconductor device for converting optical images into electrical signals. One of the challenges to be solved in the image sensor is to increase the sensitivity, i.e., the rate of converting incident light signals into electrical signals.

As illustrated in FIG. 1, one of various reasons that reduce sensitivity of the image sensor, is that the light condensed and incident into the photodiode 10 by a microlens 20 is not all absorbed due to reflection.

Accordingly, a portion of the incident light is reflected or not absorbed into a region of the photodiode 10 and disappears, which reduces the sensitivity of the image sensor.

### BRIEF SUMMARY

Embodiments provide an image sensor and a fabricating method thereof for enhancing the sensitivity by transmitting effectively incident light into a photodiode region.

In one embodiment, an image sensor includes an isolation layer, a transistor region, and a photodiode region formed on a semiconductor substrate, and a plurality of holes formed in the photodiode region. The plurality of holes can be densely formed in the photodiode region. The plurality of holes can be random or patterned shapes in the surface of the photodiode region. In one embodiment, at least one hole is formed at a design rule minimum size.

In another embodiment, a fabricating method of an image sensor includes defining an isolation layer region, a transistor region, and a photodiode region on a semiconductor substrate, forming a plurality of holes in the photodiode region, implanting first conduction type ions into the photodiode region to form a first conduction type ion implantation region, and implanting second conduction type ions into the first ion implantation region to form a second conduction type ion implantation region. In one embodiment, the plurality of holes can be formed in the photodiode region simultaneously with forming isolation trenches.

### BRIEF DESCRIPTION OF THE DRAWINGS

FIG. 1 illustrates limitations of a related art image sensor.

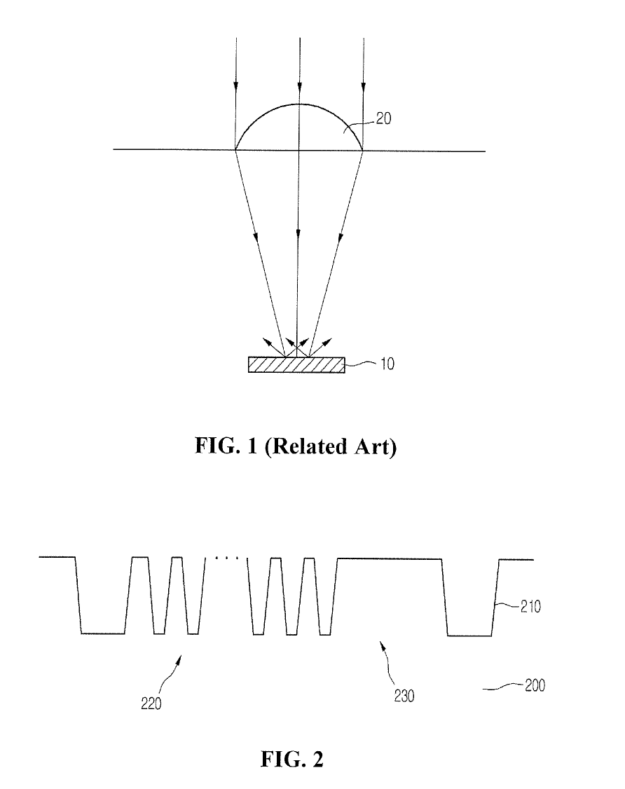

FIGS. 2 to 4 explain a fabricating method of an image sensor according to embodiments.

### DETAILED DESCRIPTION

In the descriptions of the embodiments, when each of layers, regions, pads or patterns are referred as being “on/above/over/upper” or “down/below/under/lower”, they may be directly formed on layers, regions, pad or pattern, or intervening layer, region, or patterns may be present. Therefore, the meanings should be understood based on the scope of the embodiment.

Hereinafter, an embodiment will be described in detail with reference to the accompanying drawings.

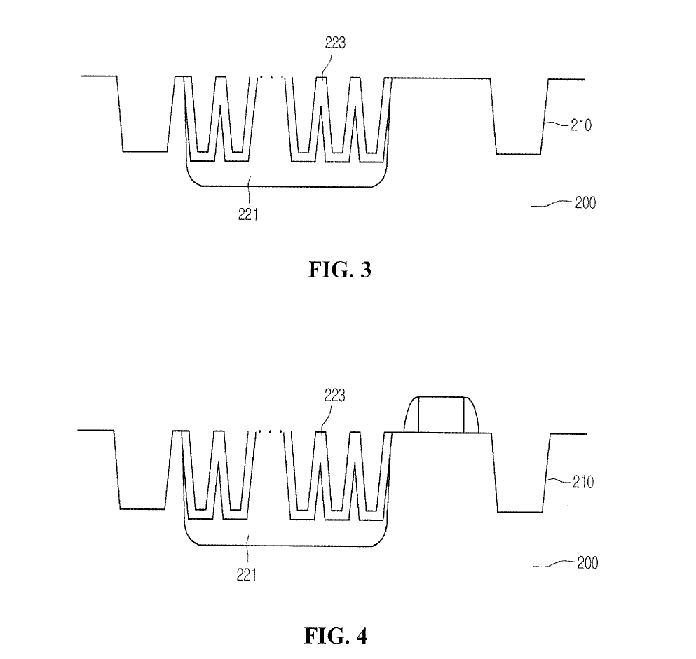

FIGS. 2 to 4 are provided to explain a fabricating method of the image sensor in accordance with embodiments.

As shown in FIG. 2, an isolation layer 210, a photodiode region 220, and a transistor region 230 can be defined on the semiconductor substrate 200, and a plurality of holes can be formed in the photodiode region 220.

The holes formed in the photodiode region 220 can be formed randomly or in various patterns in the semiconductor substrate 200. In one embodiment, the plurality of holes can be via sized holes etched into the substrate. The holes in the semiconductor substrate 200 can be formed in a trench shape, round shape, or polygonal shape. In an embodiment, the holes can be shaped the same, or multiple patters, or shapes can be used. The holes can be formed to have a predetermined depth. The holes can be densely formed in the photodiode region 220. In an embodiment, at least one hole in the photodiode region 220 is formed at a design rule minimum size. In an embodiment, the holes can be used to realize a rough patterned surface. The rough patterned surface can be a random etched formation. This can be accomplished by an etching process of an entire photodiode region. The random etched formation can be provided to a shallow depth in the photodiode region.

The holes in the photodiode region 220 can be formed during an etching process for forming the isolation layers 210 on the semiconductor substrate 200. Examples of the isolation layer 210 can include Shallow Trench Isolation (STI). In a further embodiment, a plasma treatment can be performed to treat the surface of the substrate after performing the etching process.

Referring to FIG. 3, first conduction type ions are implanted into the photodiode region 220 to form a first conduction type ion implantation region 221. Subsequently, second conduction type ions are implanted into the first conduction type ion implantation region 221 to form a second conduction type ion implantation region 223.

For example, the first conduction type ion implantation region 221 can be formed by implanting n-type dopants, and the second conduction type ion implantation region 223 can be formed by implanting p-type dopants. Alternatively, the first conduction type ion implantation region 221 can be formed by implanting p-type dopants, and the second conduction type ion implantation region 223 can be formed by implanting n-type dopants. The first conduction type ion implantation region 221 and the second conduction type ion implantation region 223 are formed as describe above to form a photodiode.

When the holes are formed in the photodiode region 220, the holes can be densely formed in the photodiode region 220. By densely forming the holes in the photodiode, an amount of incident light into the holes can be increased and the sensitivity of the image sensor can be enhanced. In an embodiment, the photodiode region 220 can be etched with as many holes of design rule minimum sizes as can fit within the area of the photodiode region 220. In another embodiment, the photodiode region 220 can be etched in a plasma etching environment to form a rough patterned surface in the photodiode region.

Subsequently, a Pre-Metal-Dielectric (PMD) layer can be formed on the semiconductor substrate 200 including transistors. At least one metal layer is formed on the PMD layer. In an embodiment, three metal layers can be formed, but more or less number of metal layers can be formed depending on the design.

Also, a color filter can be further formed above the photodiode region 220 to selectively transmit the light belonging to a predetermined wavelength band and incident from the above into the photodiode region 220 on the semiconductor substrate 200. Also, a microlens may be formed on the color filter to condense the light.

An image sensor produced using the above-described image sensor fabricating method includes an isolation layer 210, a photodiode region 220, and a transistor region 230. A plurality of holes can be formed in the photodiode region 220.

Holes in the photodiode region 220 can be formed in various patterns on the semiconductor substrate 200. The holes on the semiconductor substrate 200 can be formed in, for example, a trench shape, round shape, or polygonal shape. The holes can be formed to have a predetermined depth. The holes can be shaped the same, or multiple patterns or shapes can be used. Alternatively, the holes can be in a random formation to realize a rough patterned surface.

Also, holes in the photodiode region 220 can be formed in a minimal size in accordance with a design rule used when the isolation layer 210 is formed. By doing so, the surface area of the photodiode region 220 can be enlarged. Accordingly, an area into which light incident into a photodiode region is illuminated can be enlarged even more and thus, the sensitivity of the image device may be enhanced.

When the holes are formed in the photodiode region 220, the holes can be densely formed in the photodiode region 220. By densely forming the holes in the photodiode, an amount of incident light into the holes can be increased and the sensitivity of the image sensor can be enhanced.

The image sensor with the above-described structure enables the incident light from the outside to be transmitted into the first conduction type ion implantation region 221 and the second conduction type ion implantation region 223 through the holes formed in photodiode region 220. The incident light into the holes may be reflected on the internal surfaces of the holes, and transmitted into the first conduction type ion implantation region 221 and the second conduction type ion implantation region 223 formed in the photodiode region 220. The incident light into the holes can be transmitted into the photodiode region 220 in the semiconductor substrate with minimal light loss. Thus, as the incident light can be transmitted into the photodiode region 220 in the semiconductor region 200 with minimal loss, the sensitivity of the image device can be enhanced.

Furthermore, when a microlens for condensing light is formed in the image sensor according to the disclosure, a process margin can be enlarged for formation of the microlens. The microlens can be designed such that its focal length reaches the inside of a hole. As substantially all the incident light is transmitted into the photodiode region 220 on the semiconductor substrate, it does not matter that the focal length of the microlens has a length that reaches any part of the inside of the hole including, for example, at the entry of the hole. The focal length of the microlens can be also formed to reach the photodiode region 220.

As described above, the image sensor and the fabricating method thereof according to the embodiments can enhance the sensitivity by transmitting the incident light into the photodiode region efficiently.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
an isolation layer, a transistor region, and a photodiode region formed on a semiconductor substrate; and
a plurality of holes formed in the photodiode region.

2. The image sensor according to claim 1, wherein at least one of the plurality of holes is formed at a design rule minimum size.

3. The image sensor according to claim 1, wherein the holes in the photodiode region are formed in a trench shape, a round shape, or a polygonal shape.

4. The image sensor according to claim 1, wherein the photodiode region comprises a first conduction type ion implantation region and a second conduction type ion implantation region.

5. The image sensor according to claim 4, wherein the first conduction type ion implantation region is formed along the surface of the plurality of holes and the second conduction type ion implantation region is formed in the photodiode region below the first conduction type ion implantation region.

6. The image sensor according to claim 4, wherein the first conduction type ion is an n-type ion and the second conduction type ion is a p-type ion.

7. The image sensor according to claim 4, wherein the first conduction type ion is a p-type ion and the second conduction type ion is an n-type ion.

8. The image sensor according to claim 6, further comprising a microlens formed on the photodiode region, wherein a focal length of the microlens reaches inside of a hole.

9. The image sensor according to claim 6, further comprising a microlens formed on the photodiode region, wherein a focal length of the microlens reaches the photodiode region.

10. A method for fabricating an image sensor, the method comprising:
defining an isolation layer region, a transistor region, and a photodiode region on a semiconductor substrate;
forming a plurality of holes in the photodiode region;
forming the first conduction type ion implantation region by implanting first conduction type ions into the photodiode region having the plurality of holes;
forming the second conduction type ion implantation region by implanting second conduction type ions into the first conduction type ion implantation region.

11. The method according to claim 10, wherein forming the plurality of holes in the photodiode region comprises forming at least one hole of minimum design rule size.

12. The method according to claim 10, wherein the surfaces of the holes in the photodiode region are formed in a round shape or a polygonal shape.

13. The method according to claim 10, wherein the plurality of holes in the photodiode region are formed during an etching process for forming the isolation layer on the semiconductor substrate.

14. The method according to claim 10, wherein the plurality of holes in the photodiode region are formed in a separate etching process than that for forming the isolation layer on the semiconductor substrate.

15. The method according to claim 10, further comprising performing a plasma treatment to threat the surface after forming the plurality of holes in the photodiode region.

16. The method according to claim 10, wherein the first conduction type ion implantation region is formed along the surface of the plurality of holes and the second conduction type ion implantation region is formed in the photodiode region below the first conduction type ion implantation region.

17. The method according to claim 16, further comprising forming a microlens on the photodiode region, wherein a focal length of the microlens reaches inside of a hole.

18. The method according to claim 16, further comprising forming a microlens on the photodiode region, wherein a focal length of the microlens reaches the photodiode region.
